(19) United States
(12) Patent Application Publication
(10) Pub. No.: US 2010/0269890 A1
(43) Pub. Date: Oct. 28, 2010

(54) Polymeric Encapsulants for Photovoltaic Modules and Methods of Manufacture

(76) Inventors: Christopher John Koch, Andover, MA (US); Paul Daniel Garrett, Sturbridge, MA (US)

Correspondence Address: GOODWIN PROCTER LLP;PATENT ADMINISTRATOR, 53 STATE STREET, EXCHANGE PLACE, BOSTON, MA, 02109-2881, US

(21) Appl. No.: 12/766,378

(22) Filed: Apr. 23, 2010

Related U.S. Application Data
(60) Provisional application No. 61/172,001, filed on Apr. 23, 2009.

(51) Int. Cl. H01L 31/048; C08L 33/14; C08K 5/51; C08K 3/34; C08K 5/17; B29C 47/00; B32B 5/00

(52) U.S. Cl. 136/251; 525/55; 525/223; 524/502; 524/147; 524/442; 524/186; 264/464; 428/220

(57) ABSTRACT

An encapsulant adapted for use in a photovoltaic module includes a random terpolymer and a random copolymer. In one embodiment, the terpolymer includes ethylene, methyl acrylate, and glycidyl methacrylate, and the copolymer is a heat resistant copolymer. The encapsulant may include a carrier resin and/or one or more additives, such as a UV absorbing material, a hindered amine light stabilizer, a phosphite antioxidant, and/or a silane.

### CROSS-REFERENCE TO RELATED APPLICATION

This application claims the benefit of U.S. Provisional Patent Application No. 61/172,001, filed Apr. 23, 2009, the disclosure of which is hereby incorporated by reference herein in its entirety.

### FIELD OF THE INVENTION

The invention relates to polymeric materials for photovoltaic modules and, more specifically, to thermoplastic materials used as encapsulants.

### BACKGROUND OF THE INVENTION

Polymeric materials can be used as encapsulants of photovoltaic (PV) modules. Encapsulant layers are designed to encapsulate and protect fragile solar cells. Typically, the cells are encapsulated by a transparent or translucent encapsulant located between a transparent superstrate, such as glass, and the solar cell. A second layer of encapsulant may be used between the solar cell and a backskin or base material of the PV module. Encapsulant materials include multi-component compositions based on ethylene vinyl acetate (EVA), ionomeric polymers, poly(vinyl butyral) (PVB), polyurethane (PU), polyvinylchloride (PVC), polyethylene (e.g., metallocene-catalyzed linear low density polyethylene), polyolefin block elastomers, acid copolymers, silane-grafted or maleic anhydride-grafted linear low density polyethylenes, silicone elastomers, epoxy resins, and the like.

One encapsulant material used in PV modules is a random copolymer of ethylene vinyl acetate (EVA), with vinyl acetate content of about 25-35%, formulated with UV absorbers for long-term stability, silane coupling agents to promote adhesion to glass, and peroxide compounds to initiate crosslinking in the module lamination process. Crosslinking increases the heat resistance of EVA, i.e. resistance to creep at elevated temperatures. Creep resistance refers to the resistance to permanent deformation of a polymer subjected to a stress over a period of time as a function of temperature, and is related to the melting temperature of the polymer. For materials with low melting temperatures, such as EVA, crosslinking the polymeric material is necessary to improve the creep resistance to an acceptable level.

There are several shortcomings with EVA-based encapsulants, including the additional time needed during module lamination to allow the chemical crosslinking reaction to take place (e.g., approximately 15 minutes at 155° C.). EVA is also slightly hydrophilic, which is undesirable, because long-term water content may degrade solar cell performance, especially in certain thin film cell technologies such as Cadmium Telluride (CdTe) and Copper Indium Gallium di-Selenide (CIGS). Acetic acid produced by the crosslinking reaction may also corrode cell materials. Furthermore, the residual peroxides remaining from the crosslinking step contribute to long-term degradation (i.e., discoloration) of the EVA and of the cells themselves, in the form of corrosion. The discoloration of EVA encapsulant in photovoltaic cells is described in Ezrin, M., et al., titled “Discoloration of EVA Encapsulants in Photovoltaic Cells,” ANTEC, 3957-60 (1995), the disclosure of which is hereby incorporated by reference in its entirety.

Other PV encapsulants are described in U.S. Patent Application Publication No. 2008/0078445 (hereinafter “the '445 publication”), the disclosure of which is hereby incorporated by reference in its entirety. The '445 publication describes polyolefin copolymers including an α-olefin polymer made with a single site catalyst, such as a metallocene catalyst. In the absence of silane coupling agents, however, the polymers described in the '445 publication exhibit a low adhesion to glass. Furthermore, the polymers of the '445 publication typically are not expected to have adequate adhesion to butyl rubber sealants commonly used in the photovoltaic industry, nor would the polymers described in the '445 publication be expected to withstand creep loadings at temperatures above 90° C. due to the melting points described. The crosslinked encapsulants described in the '445 publication may have better creep resistance than the non-crosslinked encapsulant, but the crosslinked encapsulant would contain peroxides that have a negative impact on cell materials.

### SUMMARY OF THE INVENTION

Therefore, there exists a need for an inexpensive PV encapsulant material that has strong adhesion to glass, high transmittance of light, mechanical integrity at both high (to about 85° C.) and low (to about minus 40° C.) temperatures, resistance to moisture penetration, and long-term stability to UV exposure.

In one aspect, the invention relates to an encapsulant adapted for use in a photovoltaic module. The encapsulant may include a terpolymer comprising ethylene, methyl acrylate, and glycidyl methacrylate, and a heat-resistant copolymer. In one embodiment, the heat-resistant copolymer includes ethylene and glycidyl methacrylate. In another embodiment, the terpolymer includes a random terpolymer from about 40% to about 90% by weight of the encapsulant and the heat-resistant copolymer includes a random copolymer from about 10% to about 60% by weight of the encapsulant. In yet another embodiment, the random terpolymer is about 70% by weight of the encapsulant and the random copolymer is about 30% by weight of the encapsulant. In still another embodiment, the encapsulant includes a carrier resin, the random terpolymer comprises about 60% by weight of the encapsulant, the random copolymer comprises about 30% by weight of the encapsulant, and the carrier resin comprises about 10% by weight of the encapsulant.

In one embodiment, the encapsulant includes a carrier resin, the random terpolymer comprises about 55% by weight of the encapsulant, the random copolymer comprises about 30% by weight of the encapsulant, and the carrier resin comprises about 15% by weight of the encapsulant. In another embodiment, the terpolymer and the heat-resistant copolymer each have a density of greater than about 0.9 g/cc. For example, the terpolymer and the heat-resistant copolymer may each have a density of about 0.94 g/cc. In yet another embodiment, when subjected to a stress of about 1.14 psi and an elevated temperature for about 15 minutes, the encapsulant has a creep resistance of up to about 105° C. in an absence of crosslinking. In still another embodiment, when subjected to a stress of about 1.14 psi and an elevated temperature for about 15 minutes, the encapsulant has a creep resistance greater than at least one of about 105° C. and about 150° C.

In an embodiment, the encapsulant is a substantially translucent laminate having a thickness of approximately 15 mil to approximately 18 mil. In another embodiment, when subjected to testing under ASTM D1003, the encapsulant transmits a percentage of incident light greater than about 91%. In yet another embodiment, when subjected to testing under ASTM D1003, the encapsulant transmits a percentage of haze greater than about 50%.

In an embodiment, the encapsulant includes an additive of a UV absorbing material, a hindered amine light stabilizer, a phosphite antioxidant, and/or a silane. In another embodiment, the encapsulant includes a carrier resin of ethylene and methyl acrylate. In yet another embodiment, a PV module includes the encapsulant.

In another aspect, the invention relates to a method of manufacturing an encapsulant adapted for use in a photovoltaic module, including the steps of providing a terpolymer comprising ethylene, methyl acrylate, and glycidyl methacrylate, providing a heat-resistant copolymer, mixing and heating the terpolymer and the copolymer to produce a substantially homogeneous mixture, and extruding the mixture to produce the encapsulant. In one embodiment, the heat-resistant copolymer includes ethylene and glycidyl methacrylate. The method may also include the steps of providing an additive of a UV absorbing material, a hindered amine light stabilizer, a phosphite antioxidant, a silane, or combinations thereof, and mixing and heating the terpolymer, the copolymer, and the additive to produce a substantially homogeneous mixture.

In an embodiment, the method includes the step of providing a carrier resin of ethylene and methyl acrylate, and mixing and heating the terpolymer, the copolymer, the additive, and the carrier resin. In another embodiment, the terpolymer includes a random terpolymer from about 40% to about 90% by weight of the encapsulant and the heat-resistant copolymer includes a random copolymer from about 10% to about 60% by weight of the encapsulant. In yet another embodiment, the random terpolymer is about 70% by weight of the encapsulant and the random copolymer is about 30% by weight of the encapsulant. In still another embodiment, the method includes the step of providing a carrier resin, and the random terpolymer is about 60% by weight of the encapsulant, the random copolymer is about 30% by weight of the encapsulant, and the carrier resin is about 10% by weight of the encapsulant.

In an embodiment, the method includes the step of providing a carrier resin, and the random terpolymer is about 55% by weight of the encapsulant, the random copolymer is about 30% by weight of the encapsulant, and the carrier resin is about 15% by weight of the encapsulant. In another embodiment, the substantially homogeneous mixture is heated to a temperature in a range from about 300° F. to about 600° F. In yet another embodiment, the substantially homogeneous mixture is heated to a temperature of about 410° F. In still another embodiment, the method includes the step of exposing the encapsulant to a radiation dose of about 1 Mrad to about 20 Mrad, or about 7 Mrad to about 15 Mrad.

### DESCRIPTION OF THE DRAWINGS

Other features and advantages of the present invention, as well as the invention itself, can be more fully understood from the following description of the various embodiments, when read together with the accompanying drawings, in which:

FIG. 1 is a schematic cross-sectional view of a photovoltaic module according to one embodiment of the invention;

FIG. 2A is a schematic cross-sectional view of a photovoltaic module according to another embodiment of the invention;

FIG. 2B is a schematic cross-sectional view of a photovoltaic module according to yet another embodiment of the invention; and

FIG. 3 is a flowchart of a method of manufacturing an encapsulant according to one embodiment of the invention.

### DETAILED DESCRIPTION

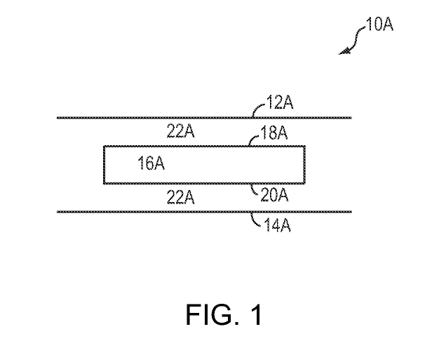

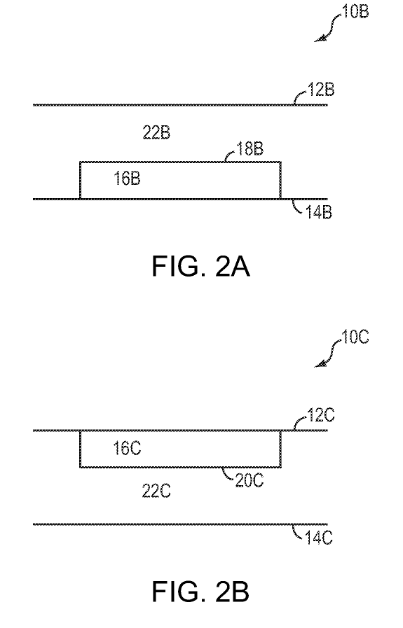

FIGS. 1, 2A, and 2B show three configurations of photovoltaic module 10A, 10B, and 10C arrangements. Each include a top sheet 12A, 12B, 12C, a solar cell 16A, 16B, 16C, an encapsulant 22A, 22B, 22C, and a base sheet 14A, 14B, 14C. The PV module 10A, depicted in FIG. 1, may be a crystalline silicon module that includes at least one layer of encapsulant 22A that is in contact with both the top sheet 12A and a top surface 18A of the cell 16A. A second layer of encapsulant 22A is in contact with the base sheet 14A and a bottom surface 20A of the cell 16A. The top sheet 12A may be a glass or plastic panel. The base sheet 14A may be a backsheet polymer film, a metal substrate, or a second glass panel. Each encapsulant layer may be about 15 mil thick. Other thicknesses are also contemplated. The encapsulant may be a substantially translucent laminate layer having a thickness of about 15 mil. The thin-film, photovoltaic module 10B, depicted in FIG. 2A, includes the cell 16B directly in contact with the base sheet 14B with only one layer of encapsulant 22B used to adhere a top sheet 12B to the base sheet 14B. Alternatively, FIG. 2B depicts a photovoltaic module 10C including the cell 16C directly in contact with the top sheet 12C with only one layer of encapsulant 22C used to adhere the base sheet 14C to the top sheet 12C.

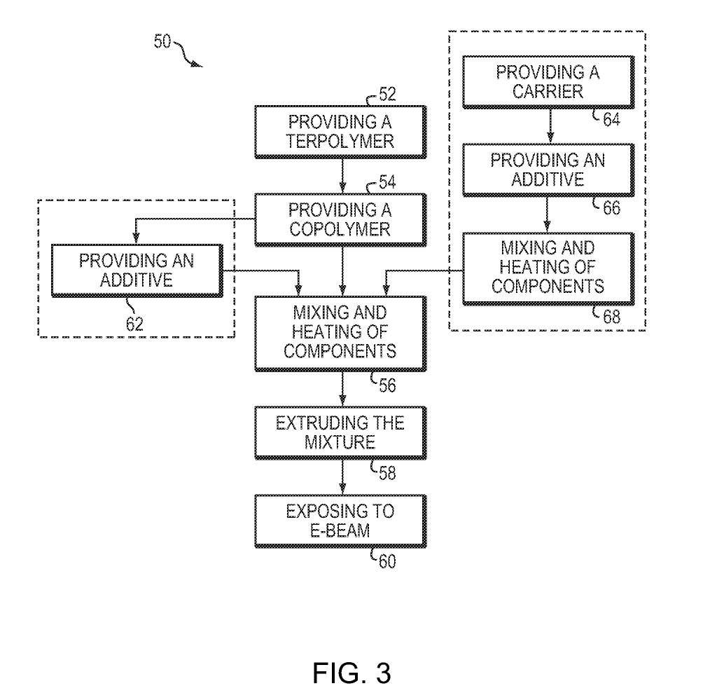

FIG. 3 shows an embodiment of a method 50 of manufacturing an encapsulant in accordance with the invention. The method begins by providing a terpolymer (step 52) and a copolymer (step 54). The terpolymer and copolymer are mixed together and heated (step 56), and the mixture is extruded (step 58). Finally, the extruded material is exposed to an electron beam (step 60). Additional steps may include providing an additive (step 62) to the mixture of terpolymer and copolymer. Alternatively or additionally, one or more additives may be introduced to the mixture by first providing a carrier resin (step 64). The additive is then added (step 66), and heated and mixed with the carrier (step 68). Each of these steps is described in more detail below.

In general, the encapsulant disclosed herein displays reduced (relative to, e.g., EVA-based encapsulants) lamination cycle times and may be laminated at lower temperatures. In certain embodiments, lamination press cycle times are about 1 minute at about 155° C. and about 3 minutes at about 125° C. The disclosed encapsulant incorporates hydrophobic components to protect the cells from moisture, and also adheres strongly to glass, polymer films, such as PET, other polyolefins, and treated fluoropolymers. Additional additives that increase moisture resistance or adhesive properties may be added, but are not required.

The encapsulant includes a blend of a terpolymer and copolymer. The terpolymer may include ethylene, methyl acrylate, and glycidyl methacrylate. More specifically, the terpolymer may be a random terpolymer with a composition of about 68% ethylene, about 24% methyl acrylate, and about 8% glycidyl methacrylate. The copolymer may include ethylene and glycidyl methacryate. Specifically, the copolymer may be a random copolymer with a composition of about 92% ethylene and about 8% glycidyl methacrylate. The terpolymer and copolymer each may have a density of greater than about 0.9 g/cc. In certain embodiments, the terpolymer and copolymer each may have a density of about 0.94 g/cc. The encapsulant blend may include about 40% to about 90% of the random terpolymer and about 10% to about 60% of the random copolymer, by weight of the encapsulant. Particularly advantageous results have been discovered using about 70% random terpolymer and about 30% random copolymer, by weight of the encapsulant. Other embodiments may include about 60% random terpolymer, about 30% random copolymer, and about 10% additive concentrate, by weight of the encapsulant. The encapsulant may also include about 55% random terpolymer, about 30% random copolymer, and about 15% additive concentrate, by weight of the encapsulant.

The blend may be extruded as a film or sheet ranging from about 1 to about 30 mils thick. Additional thickness ranges that may be utilized include about 5 to about 25 mils, and about 10 to about 20 mils. About 15 mil sheets and about 18 mil sheets may be suitable for use in many PV applications. The blend may be extruded onto a release paper carrier or fluoropolymer film, or the blend may be extruded as a free-standing film. The blend may be coextruded with other polyolefins as a layer of a multilayer application.

Both the copolymer and terpolymer are thermoplastics and hydrophobic. The terpolymer aids in adhesion to glass and the copolymer has a higher melting point than the terpolymer, thus raising the overall heat resistance. The incorporation of glycidyl methacrylate increases adhesion to glass and other substrates, such as PET films, EVA tie-layers, and other materials used in PV module backsheets. Thus, the encapsulant has a strong adhesion to glass, polyester-based films (e.g., Mylar or PET films) and butyl rubber sealants with or without the use of silane coupling agents. In that regard, the encapsulant layer described herein is particularly versatile, as it may also be used as a tie layer for PV backsheets, or for other layers where resistance to water infiltration and thermal creep is desired.

To further increase heat resistance, the film may be crosslinked by electron beam (Ebeam) treatment after extrusion. The irradiation exposure may range from about 1 to about 20 Mrad, as well as from about 7 to about 15 Mrad. Ebeam treatments of about 10 Mrad have been discovered to display particularly advantageous results. The Ebeam treatment improves high temperature creep resistance while maintaining adequate adhesion and fast processing time. By using Ebeam treatment, the film has a shorter lamination processing time and better compatibility with metals and metal oxides of solar cell components. Alternatively, the film may be crosslinked by other techniques known in the art, such as incorporating free radical initiators into the film.

In addition, a variety of additives may be used to improve overall performance of the PV module. For example, optional UV absorbers may be added to the encapsulant to ensure long-term polymer stability. Other additives that may be used to improve the long-term stability of the film under exposure to sunlight include hindered amine light stabilizers (HALS) and phosphite antioxidants. UV absorbers such as Cytec Cyasorb 531, Ciba Chimassorb 81, and BASF Uvinul 3008, may also be used. Hindered amine light stabilizers include Ciba Tinuvin 770 and BASF Uninul 407H. Phosphite antioxidants include Chemtura Naugard P. Additionally, organo-silanes may be added to increase adhesion to glass, such as those manufactured by Dow Corning (e.g., Z-6030 silane and Z-6011 silane). The encapsulant adhesion to glass is adequate without the silane additives, but may be further improved upon the addition of silanes, or silane-containing copolymers, especially with respect to retention of adhesion upon exposure to hot, wet conditions. When the encapsulant includes certain antioxidants and hindered amine light stabilizer additives, Ebeam treatment of about 12 Mrad to about 15 Mrad has been discovered to be particularly advantageous. The increase in Ebeam intensity for encapsulants including these additives is due to the function of HALS and antioxidant additives to neutralize free radicals before the radicals react with the polymer. Other additives, such as silanes and UV absorbers, do not interfere with free radicals and, if included in the encapsulant, generally do not need a higher Ebeam intensity treatment to achieve adequate adhesion. Without the hindered amine light stabilizers and antioxidant additives present, Ebeam treatment of about 7 Mrad to about 10 Mrad has been discovered to be particularly advantageous. Higher Ebeam intensity levels may be utilized, however.

Other additives contemplated include plasticizers, processing aids, flow enhancing additives, lubricants, pigments, dyes, flame retardants, impact modifiers, nucleating agents, antiblocking agents, thermal stabilizers, UV absorbers, UV stabilizers, dispersants, surfactants, chelating agents, coupling agents, adhesives, primers, reinforcement additives, and the like. Thermal stabilizers include, but are not limited to, phenolic antioxidants, alkylated monophenols, alkylhiomethylphenols hydroquinones, alkylated hydroquinones, tocopherols, hydroxylated thiodiphenyl ethers, alkylidenebisphenols, hydroxylbenzylated malonates, aromatic hydroxybenzyl compounds, triazine compounds, aminoic antioxidants, aryl amines, diaryl amines, polyaryl amines, acylaminophenols, oxamides, metal deactivators, phosphites, phosphonites, benzylphosphonates, ascorbic acid, hydroxylamines, nitrones, thiosynergists, benzofuranones, indolinones, and the like and mixtures thereof. UV absorbers include, but are not limited to, benzotriazoles, hydroxybenzophenones, hydroxyphenyl triazines, esters of substituted and unsubstituted benzoic acids, and the like and mixtures thereof. Hindered amine light stabilizers include secondary, tertiary, acetylated, N-hydrocarbyloxy substituted, hydroxyl substituted N-hydrocarbyloxy substituted, or other substituted cyclic amines which further incorporate steric hindrance, generally derived from aliphatic substitution on the carbon atoms adjacent to the amine function. Silane coupling agents include, but are not limited to, gamma-chloropropylmethoxysilane, vinyltriethoxysilane, vinyltris-(beta-methoxyethoxy)silane, gamma-methacryloxypropylmethoxysilane, vinyltriacetoxysilane, gamma-glycidoxypropyltrimethoxysilane, gamma-glycidoxypropyltriethoxysilane, beta-(3,4-epoxycyclohexyl)ethyltrimethoxysilane, vinyltrichlorosilane, gamma-mercaptopropylmethoxysilane, gamma-aminopropyltriethoxysilane, N-beta-(aminoethyl)-gamma-aminopropyltrimethoxysilane, and the like and mixtures thereof. Silane copolymers may also be used, and may include ethylene-silane copolymers such as Borealis LE4423, Dow Si-Link DFDA-5451 NT, or silane-grafted LLDPE copolymers. Terpolymers of ethylene, silane, and acrylate monomers may also be used.

Prior to film extrusion, the additives may be compounded with the base polymers or a carrier resin and extruded using a twin screw. The carrier resin may be a copolymer of about 80% ethylene and about 20% methyl acrylate, which is less expensive than the base polymers. Alternatively, one or both of the base resins may be compounded with the additives. Compounding the additives with a carrier resin (or base polymer) in an extruder at a high additive concentration forms pellets that then may be mixed with the terpolymer and copolymer pellets in the primary extrusion process.

Table A presents the formulation ranges of various components that may be utilized in the encapsulant formulation in accordance with various embodiments of the present invention.

TABLE A
Encapsulant Formulation Ranges

| | Low | High |
|---|---|---|
| Base Terpolymer | 40% | 90% |
| Base Copolymer | 10% | 60% |
| Carrier Resin | 0% | 15% |
| UV Absorber | 0% | 0.50% |
| Phosphite Antioxidant | 0% | 0.30% |
| Hindered Amine Light Stabilizer | 0% | 0.50% |
| Coupling Agent (e.g., | 0% | 2.0% |
| Dow Corning Z-6030) | | |
| Reactive Silane (e.g., | 0% | 0.10% |
| Dow Corning Z-6011) | | |

The encapsulant may be extruded using a commercial extrusion system utilized in making plastic laminate films, for example, a commercial extrusion film/coating line manufactured by Black Clawson Converting Machinery, of Fulton, N.Y. One acceptable extruder utilizes six barrel zones, and may extrude a sheet of material approximately 60 inches wide, either onto a carrier film or as a freestanding film. Upon cooling, the encapsulant sheet may be collected with a roller for further processing. The terpolymer and copolymer resins are introduced to the extruder at Zone 1, via one or more hoppers and mixed and heated to a homogeneous mixture that is extruded to produce the encapsulant film. The resins may be pre-mixed at the desired ratio, then introduced to a single hopper for transfer to the extruder. Alternatively, two independent hoppers may be utilized, and control systems may deliver the desired amount of each resin to the extruder. Pellets of the carrier resin and any additives may be introduced to the extruder at Zone 1, again via the single hopper or a third hopper. The terpolymer, copolymer, carrier resin, and the additives are mixed and heated to produce a substantially homogeneous mixture that is extruded to produce the encapsulant. In certain embodiments, the substantially homogeneous mixture may be heated to a temperature of about 300° F. to about 600° F. Other temperatures, such as about 325° F. and about 410° F. may produce particularly advantageous results. The Black Clawson extruder used in the examples is a large scale extruder suitable for commercial processes. Alternatively, smaller extruders could be utilized for evaluating the formulations by extruding, for example, about 8 inch wide encapsulant material at a rate of about 1 yard/min. Table B presents the processing parameter ranges for extruding an encapsulant in one commercial application according to the present invention.

TABLE B
Processing Parameter Ranges

| | Low | High |
|---|---|---|
| Barrel Temp. Zone 1 (° F.) | 300 | 600 |
| Barrel Temp. Zone 2 (° F.) | 300 | 600 |
| Barrel Temp. Zone 3 (° F.) | 300 | 600 |
| Barrel Temp. Zone 4 (° F.) | 300 | 600 |
| Barrel Temp. Zone 5 (° F.) | 300 | 600 |
| Barrel Temp. Zone 6 (° F.) | 300 | 600 |
| Barrel Temp. Zone 7 (° F.) | 300 | 600 |
| Screen Changer Temp. (° F.) | 300 | 600 |
| Extrusion Die Temp. (° F.) | 300 | 600 |
| Screw (rpm) | 20 | 120 |
| Line speed (yard/minute) | 10 | 30 |

### EXAMPLES AND TESTING

Several examples of encapsulants manufactured in accordance with the present invention are described below, as well as comparative examples. Comparative performance data for the Examples is also provided.

### Example 1

Example 1 was manufactured using a terpolymer (Lotader® AX 8900 sold by Akema) and a copolymer (Lotader® AX 8840 sold by Arkema). The composition is found in Table A-1.

TABLE A-1
Example 1 Composition

| Component | Percent Composition |
|---|---|
| Base Terpolymer (Lotader ® AX 8900) | 70% |
| Base Copolymer (Lotader ® AX 8840) | 30% |

Example 1 was manufactured using the processing parameters in Table B-1.

TABLE B-1
Example 1 Processing Parameters

| | |
|---|---|
| Barrel Temp. Zone 1 (° F.) | 310 |
| Barrel Temp. Zone 2 (° F.) | 330 |
| Barrel Temp. Zone 3 (° F.) | 350 |
| Barrel Temp. Zone 4 (° F.) | 400 |
| Barrel Temp. Zone 5 (° F.) | 400 |
| Barrel Temp. Zone 6 (° F.) | 410 |
| Barrel Temp. Zone 7 (° F.) | 410 |
| Screen Changer Temp. (° F.) | 410 |
| Extrusion Die Temp. (° F.) | 400 |
| Screw (rpm) | 84 |
| Line speed (yard/minute) | 20 |

Example 1 was extruded as a melt-cast film onto silicone coated release paper of 60 in.×500 yards×15 mil in size, allowed to cool, then tested as described below.

### Example 2

Example 2 was manufactured using both the terpolymer and copolymer of Example 1, a carrier resin of 80% ethylene and 20% methyl acrylate (e.g., Lotryl® 20 MA 08 sold by Arkema), and additives, as depicted in Table A-2. Example 2 was extruded as a melt-cast film onto silicone coated release paper having dimensions of approximately 60 in ×500 yards×15 mil, under the same processing conditions as Example 1.

TABLE A-2
Example 2 Composition

| Component | Percent Composition |
|---|---|
| Base Terpolymer | 55.0% |
| (Lotader ® AX 8900) | |
| Base Copolymer | 30.0% |
| (Lotader ® AX 8840) | |
| Carrier Resin | 14.15% |
| (Lotryl ® 20 MA 08) | |
| Cytec Cyasorb 531 | 0.3% |
| Chemtura Naugard P | 0.2% |
| Ciba Tinuvin 770 | 0.1% |
| Dow Corning Z-6030 silane | 0.225% |
| Dow Corning Z-6011 silane | 0.025% |

### Example 3

Example 3 was manufactured using both the terpolymer and copolymer of Example 1, the carrier resin of Example 2, and additives, as depicted in Table A-3. Example 3 was extruded as a melt-cast film onto silicone coated release paper having dimensions of approximately 60 in ×500 yards×15 mil, under the same processing conditions as Example 1, except that the barrel temperatures for zones 1 through 7 were all 325° F.

TABLE A-3
Example 3 Composition

| Component | Percent Composition |
|---|---|
| Base Terpolymer | 60.0% |
| (Lotader ® AX 8900) | |
| Base Copolymer | 30.0% |
| (Lotader ® AX 8840) | |
| Carrier Resin | 9.25% |
| (Lotryl ® 20 MA 08) | |
| Cytec Cyasorb 531 | 0.3% |
| Ciba Irgafos 168 | 0.1% |
| Ciba Tinuvin 770 | 0.1% |
| Dow Corning Z-6582 silane | 0.225% |
| Dow Corning Z-6011 silane | 0.025% |

### Example 4

Example 4 was manufactured using both the terpolymer and copolymer of Example 1, the carrier resin of Example 2, an ethylene-silane copolymer, and additives, as depicted in Table A-4. Unlike Examples 2 and 3, Example 4 did not include separate liquid silanes (e.g., Dow Corning Z-6030, Z-6011, and/or Z-6582).

TABLE A-4
Example 4 Composition

| Component | Percent Composition |
|---|---|
| Base Terpolymer | 65.0% |
| (Lotader ® AX 8900) | |
| Base Copolymer | 10.0% |
| (Lotader ® AX 8840) | |
| Silane Copolymer | 20.0% |
| (Borealis LE 4421) | |
| Carrier Resin | 4.5% |
| (Lotryl ® 20 MA 08) | |
| Cytec Cyasorb 531 | 0.3% |
| Ciba Irgafos 168 | 0.1% |
| Ciba Tinuvin 770 | 0.1% |

Example 4 was extruded on laboratory-scale equipment having a 1 in. screw diameter. This extruder produced a film approximately 12 in. wide, under the following conditions:

TABLE B-2
Example 4 Processing Parameters

| | |
|---|---|
| Barrel Temp. Zone 1 (° F.) | 375 |
| Barrel Temp. Zone 2 (° F.) | 410 |
| Barrel Temp. Zone 3 (° F.) | 410 |
| Extrusion Die Temp. (° F.) | 350 |
| Screw (rpm) | 82 |
| Line speed (yard/minute) | ~1 |

### Example 5

Example 5 was a formulation identical to that produced in Example 1, additionally irradiated by an Ebeam, at a 10 Mrad exposure. An Energy Sciences 200 kV electron beam unit was utilized operating at 180 kV and 11.7 mA in a roll-to-roll process with a line speed of 20 feet/minute.

### Example 6

Example 6 was a formulation identical to that produced in Example 2, additionally irradiated by an Ebeam, at an exposure of 12.5 Mrad. An Energy Sciences 200 kV electron beam unit was utilized operating at 180 kV and 11.7 mA in a roll-to-roll process with a line speed of 20 feet/minute.

### Comparative Example 1

Crosslinked EVA was used as Comparative Example 1. The EVA film was obtained from Specialized Technology Resources, Inc., grade 15420P/UF, in the form of sheets 18 mil thick by 48 inches wide. This type of EVA film, containing peroxides left over from processing, is used in the PV industry.

### Comparative Example 2

A film of 100% Lotader® AX 8900 was used as comparative Example 2. The film was extruded using the processing parameters in Table B-2.

### Comparative Example 3

A film of 100% Lotader® AX 8840 was used as comparative Example 3. The film was extruded using the processing parameters in Table B-2.

### Comparative Example 4

A film of 100% Lotryl® 20 MA 08 was used as comparative Example 4. The film was extruded using the processing parameters in Table B-2.

### Testing

Lamination conditions during manufacture of PV modules may be at a pressure of about 1 atm, and at a temperature of about 110° C. to about 175° C. for about 1 minute to about 15 minutes, preferably about 140° C. to about 160° C. for about 3 minutes to about 5 minutes. Other lamination conditions may be at a pressure of about 1 atm, and at a temperature ranges of about 120° C. to about 140° C., or about 145° C. to about 155° C. In general, lower temperatures will require longer times to ensure adequate adhesion.

Table C-1 presents the luminous transmittance, adhesion to glass, and shear creep resistance for Examples 1-6 and Comparative Examples 1-4, which were laminated to glass with a flexible polymer backing for adhesion and creep testing. All of the Examples and Comparative Examples in Table C-1 were laminated under the same conditions (i.e., 155° C. at 1 atm with 7 minutes pump time and 8 minutes press time). Lamination was performed using a SPI-Laminator 350 vacuum laminator manufactured by Spire Corp., of Bedford, Mass.

TABLE C-1
Performance of Examples and Comparative Examples

| | | | Adhesion Retention | |
|---|---|---|---|---|
| | | Initial | after 1000 Hours | |
| | Luminous | Adhesion | of 85° C./85% RH | Shear Creep |
| | Trans- | to Glass | Exposure | Resistance |
| | mittance | (lbs/in.) | (% of Initial) | (° C.) |
| Example 1 | >91% | 56 | <50 | 105 |
| Example 2 | >91% | 65 | >50 | 105 |
| Example 3 | >91% | >60 | >50 | 105 |
| Example 4 | >91% | >60 | >50 | 105 |
| Example 5 | >91% | 45 | >50 | >130 |
| Example 6 | >91% | 45 | >50 | >130 |
| Comparative | >91% | 60 | >50 | >130 |
| Example 1 | | | | |
| Comparative | >91% | 66 | <50 | <80 |
| Example 2 | | | | |
| Comparative | >91% | 11 | <50 | 100 |
| Example 3 | | | | |
| Comparative | >91% | <3 | N/A | <80 |
| Example 4 | | | | |

Luminous transmittance was measured in accordance with ASTM D1003. All Examples display acceptable luminous transmittance (as compared to Comparative Example 1). The encapsulant may transmit a percentage of incident light greater than about 50%. The encapsulant may transmit a percentage of incident light greater than about 91%.

Adhesion to glass was measured using an Instron tensile test device in about 90 degree geometry at about 12 inches/minute test rate, in accordance with ASTM D6862. Adhesion testing was performed on samples of about 2 inches by about 8 inches in size by extruding the encapsulant onto glass and layering a crystal-silicon wafer between another layer of encapsulant in contact with a backsheet. The backsheet used for the examples was a flexible backsheet of Proteckt, manufactured by Madico Corp., of Woburn, Mass., and includes a fluoropolymer film, polyester film, and non-crosslinked EVA.

Minimum acceptable adhesion to glass value for typical PV applications is about 30 lb/inch. As can be seen in Table C-1, the initial adhesion to glass value for each of the Examples exceeded 30 lb/inch. Notably, however, the initial adhesion values for Comparative Example 3 (the encapsulant comprising 100% copolymer) and Comparative Example 4 (the encapsulant comprising 100% carrier resin) were significantly below the acceptable minimum value. This demonstrates that using only Lotader® AX 8840 (an exemplary copolymer) or only Lotryl® 20 MA 08 (80% ethylene and 20% methyl acrylate) exhibits insufficient adhesion to glass.

In addition to the initial adhesion measurements, adhesion to glass was also measured after the encapsulants of Examples 1-6 and Comparative Examples 1-3 were exposed to 85° C. and 85 percent relative humidity for 1000 hours. As shown in Table C-1, after being exposed to this heat and humidity, the encapsulants of Examples 2-6 and Comparative Example 1 retained greater than 50 percent of the initial adhesion value. By contrast, following the same heat and humidity exposure, the encapsulants of Example 1 and Comparative Examples 2 and 3 retained less than 50 percent of the initial adhesion value. Comparative Example 4 was not tested under the higher humidity conditions, since its initial adhesion to glass was so low.

Additional experiments were performed on the encapsulants of Examples 1 and 5 by laminating with press times of about 1 minute to about 7 minutes at about 155° C., which resulted in no decrease in adhesion of encapsulant to glass. The adhesion does not decrease even with temperature decreased to about 120° C., unlike EVA encapsulants which show poor adhesion when heated only to 120° C., and which also require longer cycle times. Specifically, utilizing a vacuum lamination pump time of about 7 minutes and a press time of about 1 minute, Example 1 had an adhesion of 57 lb/inch and Example 5 had an adhesion of 40 lb/inch. This demonstrates the short cycle time the Examples require to achieve adequate adhesion. EVA, however, typically requires a vacuum lamination pump time of about 2 minutes to about 7 minutes, with a press time of about 7 minutes to about 15 minutes to achieve adequate crosslinking and outgassing of crosslinking reaction by-products.

The shear creep resistance data was obtained by applying a stress of about 1.14 psi by hanging a weight from a flexible film attached to the encapsulant that was laminated to glass. The sample was placed in an oven in a vertical orientation (with the weight hanging from the film) at about 80° C. and the temperature was increased incrementally every 30 minutes until the weighted film separated from the laminate sample. Minimum acceptable shear creep resistance values for PV applications is about 85° C. As can be seen in Table C-1, each of the Examples exceeded this amount. In fact, certain examples achieve a creep resistance up to about 105° C. without crosslinking, and a creep resistance above about 150° C. with Ebeam treatment. Notably, however, Comparative Example 2 (the encapsulant comprising 100% terpolymer) is significantly below the acceptable minimum value. This demonstrates that using only Lotader® AX 8900 (an exemplary terpolymer) presents insufficient creep resistance for typical PV applications.

UV resistance data was obtained by laminating the samples as described above to low-iron glass and exposing the films in a xenon arc weatherometer for about 1000 hours. A Colorquest II system manufactured by Hunterlab Instruments was used to perform the measurements. Under ASTM D2244, ΔE represents the color change in the sample from its original color after about 1000 hours of exposure. A ΔE less than about 2.0 is considered negligible. As seen in Table C-2, the ΔE after 1000 hours of exposure for Examples 1, 2, 3 and 5 and Comparative Examples 1 and 3 was less than 2.0.

TABLE C-2
ΔE Comparison

| | ΔE |
|---|---|
| Example 1 | 1.2 |
| Example 2 | 1.5 |
| Example 3 | 1.5 |
| Example 5 | 1.6 |
| Comparative | 1.4 |
| Example 1 | |
| Comparative | 1.3 |
| Example 3 | |

For photovoltaic applications, it is important to keep moisture away from the solar cell components to prevent corrosion. Moisture Vapor Transmission Rates (MVTR) were obtained for certain examples according to ASTM F1249 at about 38° C. and about 100% relative humidity. As seen in Table C-3, the MVTR for three embodiments of the encapsulant are significantly better than the EVA standard encapsulant represented in Comparative Example 1.

TABLE C-3
MVTR Comparison

| | MVTR |
|---|---|
| | (g/m²/day) |
| Example 1 | 16.4 |
| Example 2 | 16.1 |
| Example 5 | 16.6 |
| Comparative | 43.2 |
| Example 1 | |
| Comparative | 42.6 |
| Example 2 | |
| Comparative | 13.8 |
| Example 4 | |

While there have been described herein what are to be considered exemplary and preferred embodiments of the present invention, other modifications of the invention will become apparent to those skilled in the art from the teachings herein. The particular compositions, methods of manufacture, and geometries disclosed herein are exemplary in nature and are not to be considered limiting. It is therefore desired to be secured in the appended claims all such modifications as fall within the spirit and scope of the invention. Accordingly, what is desired to be secured by Letters Patent is the invention as defined and differentiated in the following claims, and all equivalents.

What is claimed is:

1. An encapsulant adapted for use in a photovoltaic module, the encapsulant comprising:
a terpolymer comprising ethylene, methyl acrylate, and glycidyl methacrylate; and
a heat-resistant copolymer.

2. The encapsulant of claim 1, wherein the heat-resistant copolymer comprises ethylene and glycidyl methacrylate.

3. The encapsulant of claim 2, wherein the terpolymer comprises a random terpolymer comprising about 40% to about 90% by weight of the encapsulant and wherein the heat-resistant copolymer comprises a random copolymer comprising about 10% to about 60%, by weight of the encapsulant.

4. The encapsulant of claim 3, wherein the random terpolymer comprises about 70% by weight of the encapsulant, and wherein the random copolymer comprises about 30% by weight of the encapsulant.

5. The encapsulant of claim 3, further comprising a carrier resin, and wherein the random terpolymer comprises about 60% by weight of the encapsulant, wherein the random copolymer comprises about 30% by weight of the encapsulant, and wherein the carrier resin comprises about 10% by weight of the encapsulant.

6. The encapsulant of claim 3, further comprising a carrier resin, and wherein the random terpolymer comprises about 55% by weight of the encapsulant, wherein the random copolymer comprises about 30% by weight of the encapsulant, and wherein the carrier resin comprises about 15% by weight of the encapsulant.

7. The encapsulant of claim 1, wherein the terpolymer and the heat-resistant copolymer each comprise a density of greater than about 0.9 g/cc.

8. The encapsulant of claim 7, wherein the terpolymer and the heat-resistant copolymer each comprise a density of about 0.94 g/cc.

9. The encapsulant of claim 1, wherein when subjected to a stress of about 1.14 psi and an elevated temperature for about 15 minutes, the encapsulant comprises a creep resistance of up to about 105° C. in an absence of crosslinking.

10. The encapsulant of claim 1, wherein when subjected to a stress of about 1.14 psi and an elevated temperature for about 15 minutes, the encapsulant comprises a creep resistance greater than at least one of about 105° C. and about 150° C.

11. The encapsulant of claim 1, wherein the encapsulant comprises a substantially translucent laminate comprising a thickness of approximately 15 mil to approximately 18 mil.

12. The encapsulant of claim 11, wherein when subjected to testing under ASTM D1003, the encapsulant transmits a percentage of incident light greater than about 91%.

13. The encapsulant of claim 11, wherein when subjected to testing under ASTM D1003, the encapsulant transmits a percentage of haze greater than about 50%.

14. The encapsulant of claim 1, further comprising an additive comprising at least one of a UV absorbing material, a hindered amine light stabilizer, a phosphite antioxidant, and a silane.

15. The encapsulant of claim 14, further comprising a carrier resin comprising ethylene and methyl acrylate.

16. A PV module comprising the encapsulant of claim 1.

17. A method of manufacturing an encapsulant adapted for use in a photovoltaic module, the method comprising the steps of:
providing a terpolymer comprising ethylene, methyl acrylate, and glycidyl methacrylate;
providing a heat-resistant copolymer;
mixing and heating the terpolymer and the copolymer to produce a substantially homogeneous mixture; and
extruding the mixture to produce the encapsulant.

18. The method of claim 17, wherein the heat-resistant copolymer comprises ethylene and glycidyl methacrylate.

19. The method of claim 18, further comprising the steps of:
providing an additive selected from the group consisting of a UV absorbing material, a hindered amine light stabilizer, a phosphite antioxidant, a silane, and combinations thereof; and
mixing and heating the terpolymer, the copolymer, and the additive to produce a substantially homogeneous mixture.

20. The method of claim 19, further comprising the step of providing a carrier resin comprising ethylene and methyl acrylate, and mixing and heating the terpolymer, the copolymer, the additive, and the carrier resin.

21. The method of claim 18, wherein the terpolymer comprises a random terpolymer comprising about 40% to about 90% by weight of the encapsulant, and wherein the heat-resistant copolymer comprises a random copolymer comprising about 10% to about 60% by weight of the encapsulant.

22. The method of claim 21, wherein the random terpolymer comprises about 70% by weight of the encapsulant, and wherein the random copolymer comprises about 30% by weight of the encapsulant.

23. The method of claim 21, further comprising providing a carrier resin, and wherein the random terpolymer comprises about 60% by weight of the encapsulant, wherein the random copolymer comprises about 30% by weight of the encapsulant, and wherein the carrier resin comprises about 10% by weight of the encapsulant.

24. The method of claim 21, further comprising providing a carrier resin, and wherein the random terpolymer comprises about 55% by weight of the encapsulant, wherein the random copolymer comprises about 30% by weight of the encapsulant, and wherein the carrier resin comprises about 15% by weight of the encapsulant.

25. The method of claim 18, wherein the substantially homogeneous mixture is heated to a temperature in a range from about 300° F. to about 600° F.

26. The method of claim 25, wherein the substantially homogeneous mixture is heated to a temperature of about 410° F.

27. The method of claim 18, further comprising the step of exposing the encapsulant to a radiation dose of about 1 Mrad to about 20 Mrad.

28. The method of claim 27, further comprising the step of exposing the encapsulant to a radiation dose of about 7 Mrad to about 15 Mrad.

29. An encapsulant produced by the method of claim 17.
